(19) United States
(12) Patent Application Publication
(10) Pub. No.: US 2017/0077389 A1
(43) Pub. Date: Mar. 16, 2017

(54) EMBEDDED MEMORY IN INTERCONNECT STACK ON SILICON DIE

(71) Applicant: INTEL CORPORATION, Santa Clara, CA (US)

(72) Inventors: Donald W. NELSON, Beaverton, OR (US); M Clair WEBB, North Logan, UT (US); Patrick MORROW, Portland, OR (US); Kimin JUN, Hillsboro, OR (US)

(73) Assignee: INTEL Corporation

(21) Appl. No.: 15/122,911

(22) PCT Filed: Jun. 16, 2014
(86) PCT No.: PCT/US2014/042577

§ 371 Date: Aug. 31, 2016

(51) Int. Cl. H01L 43/02; H01L 27/22; H01L 43/12; H01L 43/08; H01L 43/10

(52) U.S. Cl. CPC H01L 43/02; H01L 43/08; H01L 43/10; H01L 43/12; H01L 27/228

(57) ABSTRACT

A method including forming a plurality of first interconnects and a plurality of second interconnects on opposite sides of an integrated circuit device layer including a plurality of circuit devices, wherein forming ones of the plurality of first interconnects and a plurality of second interconnects includes embedding memory devices therein. An apparatus including a substrate including a plurality of first interconnects and a plurality of second interconnects on opposite sides of an integrated circuit device layer including a plurality of circuit devices, wherein ones of the plurality of first interconnects and a plurality of second interconnects includes memory devices embedded therein.

### BACKGROUND

Field

Integrated circuits and more particularly, monolithic three-dimensional integrated circuits.

Description of Related Art

Monolithic integrated circuits (ICs) generally include a number of transistors, such as metal oxide semiconductor field effect transistors (MOSFETs) fabricated over a planar substrate, such as a silicon wafer. Lateral scaling of IC dimensions is becoming more difficult with MOSFETs gate dimensions now below 20 nm. As device sizes continue to decrease, there will come a point where it becomes impractical to continue standard planar scaling. This inflection point could be due to economics or physics, such as prohibitively high capacitance, quantum-based variability, interconnect resistivity as interconnects continue to scale, and lithography operations for interconnect lines and vias. Stacking of devices in a third dimension, typically referred to as vertical scaling, or three-dimensional (3D) integration, is a promising path toward greater transistor density.

### BRIEF DESCRIPTION OF THE DRAWINGS

FIG. 1 shows one embodiment of a monolithic 3D IC including memory devices embedded in an interconnect region.

FIG. 2 illustrates a schematic of a non-volatile memory bit cell that is an STT-MRAM memory bit cell as an example memory device in the structure of FIG. 1.

FIG. 3 shows a cross-sectional side view of an embodiment of a structure including a device layer or a substrate and a plurality of first interconnects juxtaposed to the device layer.

FIG. 4 shows the structure of FIG. 3 following the connection of the structure to a carrier wafer.

FIG. 5 shows the structure of FIG. 4 following the removal of a portion of the substrate.

FIG. 6 shows the structure of FIG. 5 following the formation of memory devices on the structure.

FIG. 7 shows the structure of FIG. 6 following the introduction of a second plurality of interconnects on the structure.

FIG. 8 shows the structure of FIG. 7 following the introduction of the contact points to ones of the plurality of interconnects.

FIG. 9 shows a cross-sectional side view of a second embodiment of a structure including a device layer on the substrate and a plurality of first interconnects juxtaposed to the device layer and memory devices embedding in the interconnect region.

FIG. 10 shows the structure of FIG. 9 following the connection of the structure to a carrier wafer.

FIG. 11 shows the structure of FIG. 10 following the removal of a portion of the substrate from the structure.

FIG. 12 shows the structure of FIG. 11 following the introduction of a plurality of second interconnects and connection of ones of such interconnects to ones of the memory devices and contacts introduced or formed to ones of the interconnects.

FIG. 13 is an interposer implementing one or more embodiments.

FIG. 14 illustrates an embodiment of a computing device.

### DETAILED DESCRIPTION

An integrated circuit (IC) and a method of forming and using an IC are disclosed. In one embodiment, a monolithic three-dimensional (3D) IC and its method of manufacture and use is described that, in one embodiment, includes memory, including but not limited to, resistive random access memory (ReRAM), magnetoresistive RAM (MRAM) such as spin transfer torque (STT)-MRAM, phase change or other memory devices placed in an interconnect region. Representatively, a monolithic 3D IC includes a plurality of first interconnects and a plurality of second interconnects on opposite sides of an integrated circuit device layer with memory devices embedded in at least one of the plurality of first interconnects and the plurality of second interconnects. The memory devices are coupled to respective ones of the plurality of first and second interconnects and to respective ones of circuit devices in the device layer. In one embodiment, the dimensions of the plurality of first and second interconnects are different so that memory devices are connected to fine pitch interconnects on one side of the device layer and gated through circuit devices in the device layer to thicker interconnects on the other side of the device layer. The configuration allows for dense memories as well as freeing area of a device layer for circuits other than memory.

In the following description, various aspects of the illustrative implementations will be described using terms commonly employed by those skilled in the art to convey the substance of their work to others skilled in the art. However, it will be apparent to those skilled in the art that embodiments may be practiced with only some of the described aspects. For purposes of explanation, specific numbers, materials and configurations are set forth in order to provide a thorough understanding of the illustrative implementations. However, it will be apparent to one skilled in the art that the embodiments may be practiced without the specific details. In other instances, well-known features are omitted or simplified in order not to obscure the illustrative implementations.

Various operations will be described as multiple discrete operations, in turn, in a manner that is most helpful in understanding the embodiments described herein, however, the order of description should not be construed to imply that these operations are necessarily order dependent. In particular, these operations need not be performed in the order of presentation.

Implementations may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope.

A plurality of transistors, such as metal-oxide-semiconductor field-effect transistors (MOSFET or simply MOS transistors), may be fabricated on the substrate such as in device layers as will be noted herein. In various implementations, the MOS transistors may be planar transistors, nonplanar transistors including vertically-stacked transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that embodiments may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations, the gate electrode may consist of a combination of U-shaped structures and planar, non-U-shaped structures. For example, the gate electrode may consist of one or more U-shaped metal layers formed atop one or more planar, non-U-shaped layers.

In some implementations, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

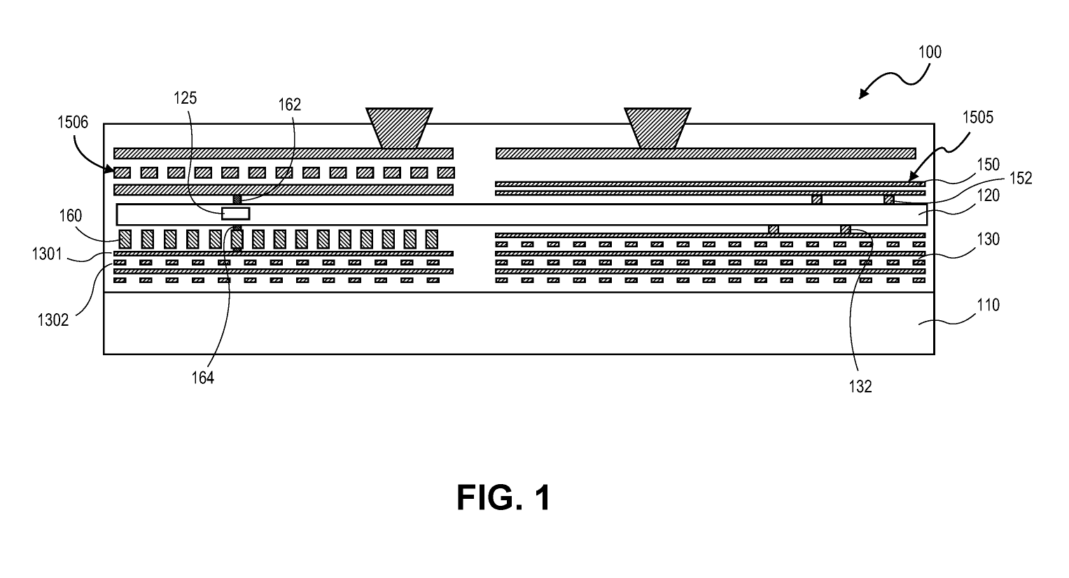

FIG. 1 shows one embodiment of a monolithic 3D IC including memory devices embedded in an interconnect region. Referring to FIG. 1, structure 100 includes substrate 110 that is, for example, a single crystal semiconductor substrate (e.g., single crystal silicon). Substrate 110 includes device layer 120 that, in this embodiment, includes a number of devices 125 (e.g., transistor devices). In one embodiment, devices 125 are low power range state of the art typically fast devices including logic devices such as FinFETs or other reduced formfactor devices that can generally be arranged on a device layer at a higher pitch than higher voltage range devices.

In the embodiment illustrated in FIG. 1, device layer 120 is disposed between plurality of first interconnects 130 and plurality of second interconnects 150. In one embodiment, one or more devices in device layer 120 is connected to one or both of interconnects associated with plurality of first interconnects 130 and plurality of second interconnects 150. Plurality of first interconnects 130, in one embodiment, have dimensions selected to accommodate, for example, the impedance of an electrical load associated with devices (device 125) in device layer 120 (e.g., impedance matching). FIG. 1 shows ones of devices of device layer 120 connected to ones of plurality of first interconnects 130 through contacts 132. Plurality of second interconnects 150 include, in one embodiment, similarly dimensioned interconnects as those of plurality of first interconnects and interconnects having dimensions that are larger (e.g., thicker) than the plurality of first interconnects. FIG. 1 shows interconnects 1505 that have dimensions similar to interconnects of plurality of first interconnects 130 and interconnects 1506 having dimensions that are larger than dimension of ones of the plurality of first interconnects. Representatively, interconnects of plurality of first interconnects 130 have a thickness on the order of at least 0.67 times a gate pitch and interconnects 1506 of plurality of second interconnects 150 have a thickness on the order of greater than 100 to 1000 times the thickness of plurality of first interconnects 130. In one embodiment, interconnects 1505 are connected to devices of device layer 120 through contacts 152.

Structure 100 in FIG. 1 also includes memory devices embedded in the plurality of first interconnects 130. FIG. 1 shows memory device 160 of, for example, ReRAM, MRAM, phase change or other device type. In one embodiment, ones of the memory devices are connected at one side to ones of plurality of first interconnects 130 and another side is gated through ones of devices 125 in device layer 120 to ones of plurality of second interconnects 150, notably to interconnects 1506.

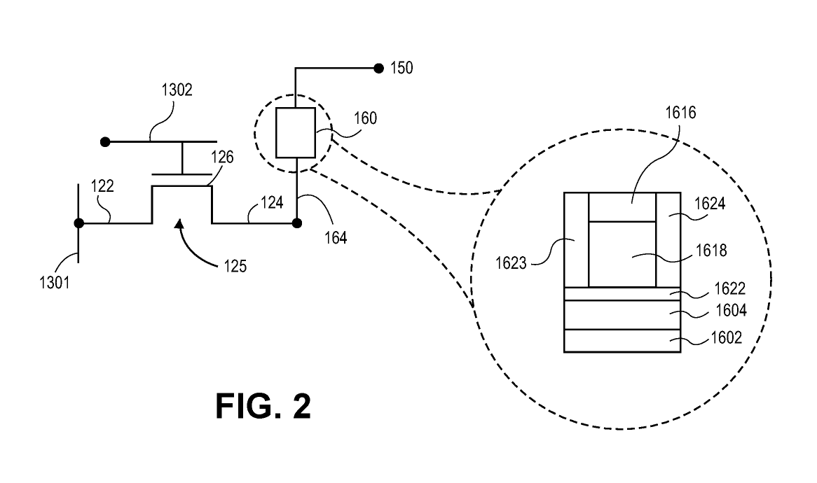

FIG. 2 illustrates a schematic of a non-volatile memory bit cell that is an STT-MRAM memory bit cell as an example memory device in the structure of FIG. 1. Referring to FIG. 2, the bit cell includes STT-MRAM memory element or component 160. As shown in the inset, where STT-MRAM memory component 160 is a spin transfer torque element, such element representatively includes bottom electrode 1602 of, for example, ruthenium with fixed magnetic layer 1604 of, for example, cobalt-iron-boron (CoFeB) adjacent bottom electrode 1602; top electrode 1616 of, for example, tantalum adjacent free magnetic layer 1618 of, for example, CoFeB; and tunneling barrier or dielectric layer 1622 of, for example, magnesium oxide (MgO) disposed between fixed magnetic layer 1604 and free magnetic layer 1618. In an embodiment, a spin transfer torque element is based on perpendicular magnetism. Finally, first dielectric element 1623 and second dielectric element 1624 may be formed adjacent to top electrode 1616, free magnetic layer 1118 and tunneling barrier dielectric layer 1622.

STT-MRAM memory component 160 is connected to one of plurality of second interconnects 150 (a bit line). Top electrode 1616 may be electrically connected to the bit line. STT-MRAM memory component 160 is also connected to access transistor 125 associated with device layer 120 (see FIG. 1). Access transistor 125 includes a diffusion region including junction region 122 (source region), junction region 124 (drain region), a channel region between or separating the junction regions and gate electrode 126 on the channel region. As illustrated, STT-MRAM memory component 160 is connected to junction region 124 of access transistor 125 by contact 164. Bottom electrode 1602 is connected to the junction region. Junction region 122 in the bit cell is connected to one of plurality of first interconnects 130 (source line 1301). Finally, gate electrode 126 is electrically connected to word line 1302.

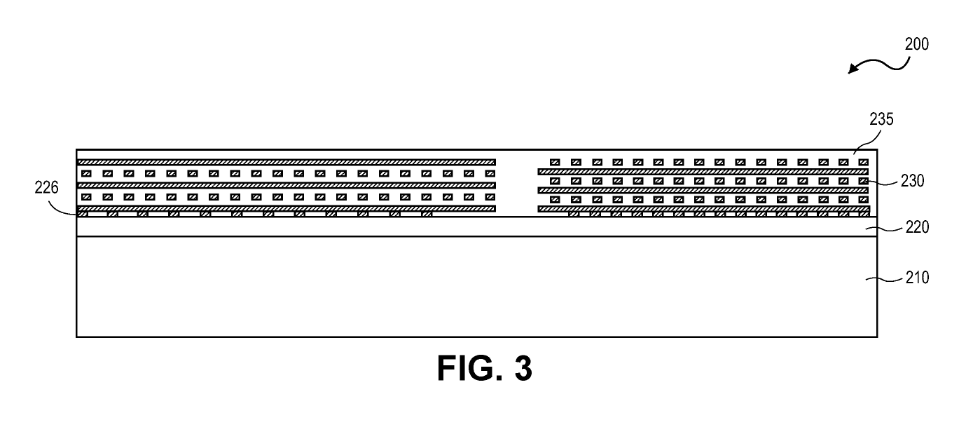

FIGS. 3-8 describe one method of forming a monolithic 3D IC. FIG. 3 shows substrate 210 of, for example, a single crystal semiconductor substrate (e.g., a silicon substrate). Disposed on substrate 210 is device layer 220 including, in one embodiment, an array or arrays of high pitch, fast devices, such as FinFETs or other state of art transistor devices. FIG. 3 also shows plurality of interconnects 230 juxtaposed to or on device layer 220. Ones of plurality of interconnects 230 are connected to ones of devices in device layer 220 through, for example, contacts 226. In one embodiment, plurality of interconnects 230 are a copper material patterned as known in the art. Device layer contacts (e.g., contacts 226) between circuit devices and a first level interconnect may representatively be a tungsten or copper material and inter level contacts between interconnects are, for example, a copper material. The interconnects are insulated from one another and from the devices by dielectric materials such as an oxide. FIG. 3 shows dielectric layer 235 juxtaposed to or disposed on an ultimate level of plurality of interconnects 230 (as viewed).

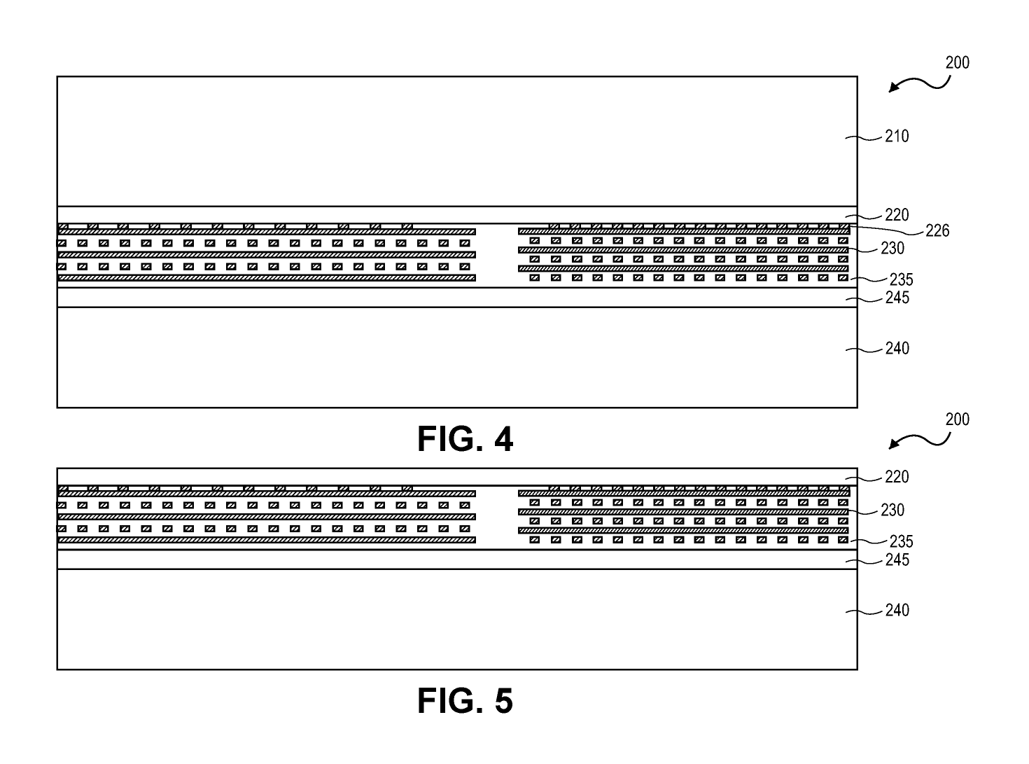

FIG. 4 shows the structure of FIG. 3 following the connection of the structure to a carrier wafer. In the illustrated embodiment, structure 200 from FIG. 3 is inverted and bonded to carrier wafer 240. FIG. 4 shows carrier wafer 240 of, for example, a single crystal semiconductor material or a ceramic or similar material. Disposed on carrier wafer 240, in one embodiment, is dielectric layer 245. FIG. 4 shows carrier wafer bonded to the structure such that dielectric layer 235 on plurality of interconnects 230 is adjacent to dielectric layer 245 of a carrier wafer (a dielectric bond).

FIG. 5 shows the structure of FIG. 4 following the removal of a portion of substrate 210. In one embodiment, substrate 210 is reduced to expose device layer 220. Representatively, a portion of substrate 210 can be removed by a mechanical mechanism (e.g., grinding) or other mechanism (e.g., etching). FIG. 5 shows structure 200 including exposed device layer 220 on a top surface of the structure as viewed.

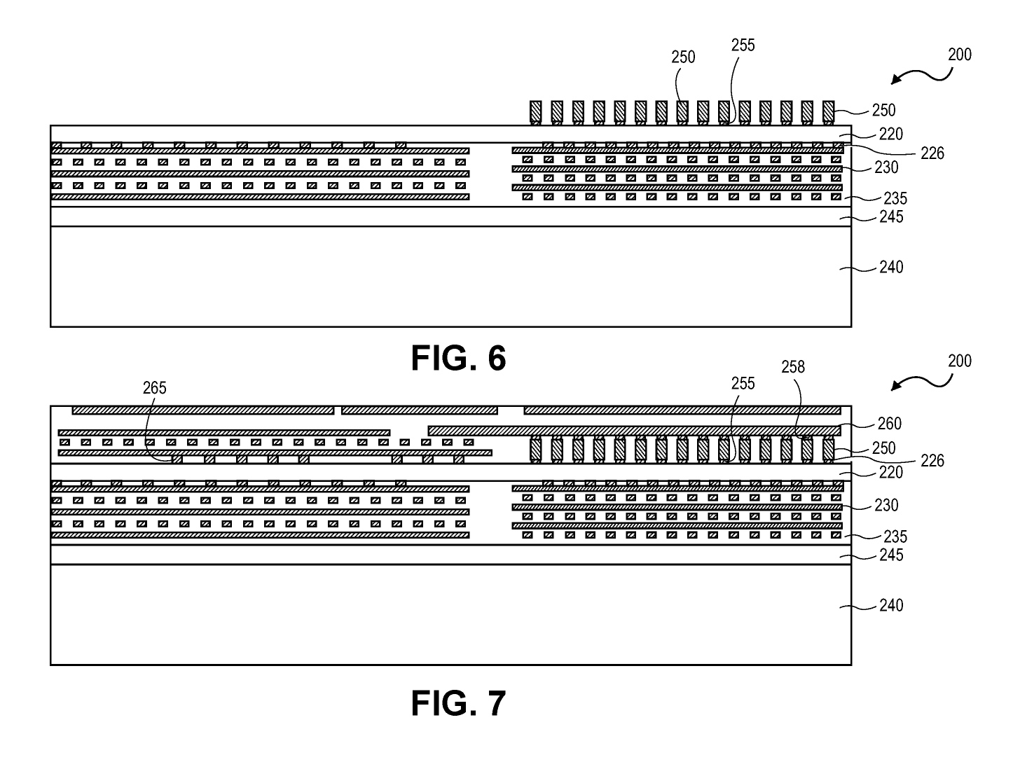

FIG. 6 shows the structure of FIG. 5 following the formation of memory devices on the structure. FIG. 6 shows memory elements or devices 250 such as ReRAM, MRAM or phase change devices connected to devices in device layer 220 through contacts 255. It is appreciated that such devices are also, in one embodiment, connected to ones of plurality of interconnects 230 through, for example, contacts 226.

FIG. 7 shows the structure of FIG. 6 following the introduction of a second plurality of interconnects on the structure. FIG. 7 shows plurality of interconnects 260 juxtaposed to device layer 220 and to memory devices 250. In one embodiment, a dimension of ones of plurality of interconnects 250 are larger (e.g., thicker) than a corresponding dimension of ones of plurality of interconnects 230. In one embodiment, plurality of interconnects 260 are a copper material and pattern as known in the art. FIG. 7 shows contacts 258 between respective ones of memory devices 250 and ones of plurality of interconnects 260. FIG. 7 also shows ones of plurality interconnects 250 connected to devices in device layer 220 through, for example, contacts 265. Device layer contacts (contacts 265) between devices on a first level interconnect of plurality of interconnects 260 may representatively be a tungsten or copper material and inter level contacts between interconnects are, for example, a copper material. As illustrated, ones of plurality of interconnects 260 connected to devices in device layer 220 may have dimension less than (e.g., thinner than) dimensions of interconnects connected to memory devices 250. The interconnects are insulated from one another then from the device layer and memory devices by dielectric material (e.g., an oxide).

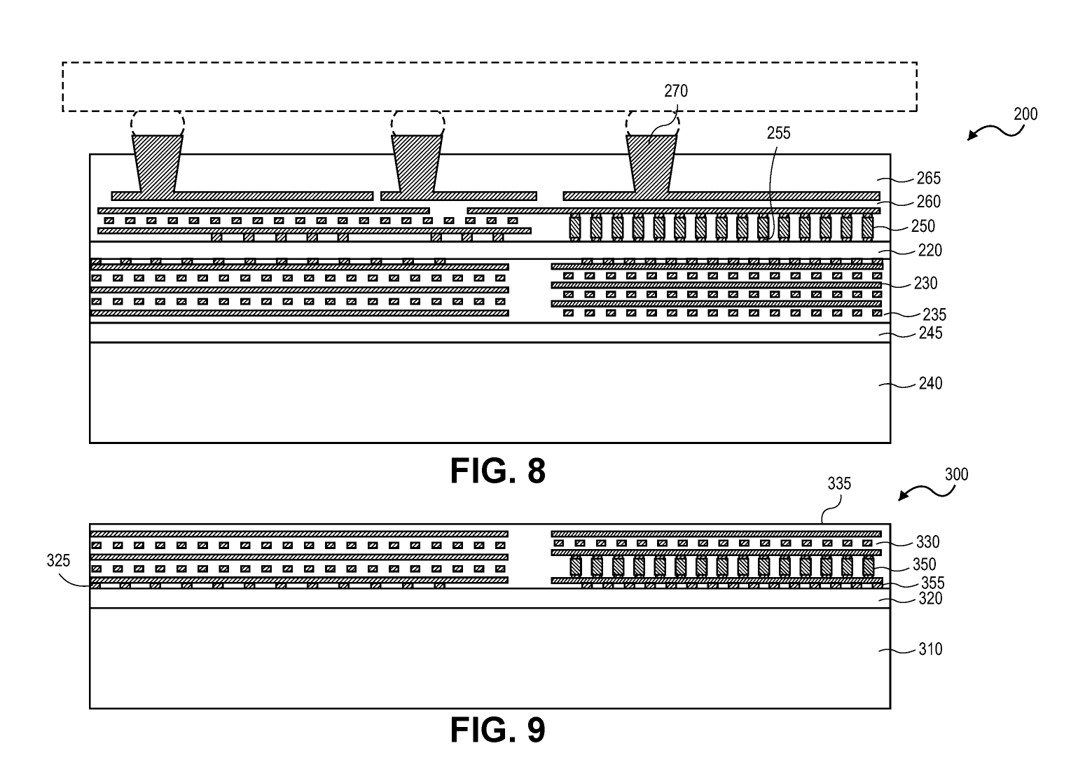

FIG. 8 shows the structure of FIG. 7 following the introduction of contact points 270 to ones of plurality of interconnects 260. Such contacts may also include a metallization layer on the structure above plurality of interconnects 260 (as viewed). FIG. 8 also shows passivation layer 165 of, for example, an oxide to passivate the surface of structure 200. Contact points 270 may be used to connect structure 200 to a substrate such as a package substrate. Once formed, the structure, if formed at a wafer level, may be singulated into a discreet monolithic 3D IC. FIG. 8 representatively shows structure 200 after singulation and illustrates in ghost lines the connection of the structure to a package through solder connections to contact points 270.

FIGS. 9-12 show a second embodiment of a method of forming a monolithic 3D IC.

FIG. 9 shows substrate 310 of, for example, a single crystal semiconductor material such as single crystal silicon. Disposed on substrate 310 is device layer 320 including an array or arrays of relatively high speed devices such as high speed logic devices (e.g., FinFETs). Juxtaposed on device layer 320 in FIG. 9 is plurality of interconnects 330 having memory elements or devices 350 embedded therein. Memory devices 350 are representatively selected from ReRAM, MRAM, phase change or other devices and formed as known in the art. Plurality of interconnects 330, in one embodiment, have dimensions that are compatible (e.g., impedance matched) to the fine pitch, high speed devices in device layer 320. Such plurality of interconnects 330 may be formed by processes as known in the art. FIG. 9 shows device level contacts 325 between devices in device layer 320 and ones of plurality of interconnects 330. FIG. 9 also shows contacts 355 between memory devices 350 and devices in device layer 320. Device level contacts 325 and 355 may representatively be a tungsten or copper material. Contacts between ones of plurality of interconnects 330 are representatively a copper material. Ones of plurality of interconnects 330 and memory elements are isolated from one another by dielectric material such as an oxide. FIG. 9 also shows passivation layer 335 of a dielectric material overlying the ultimate ones of plurality of interconnects 330 (as viewed).

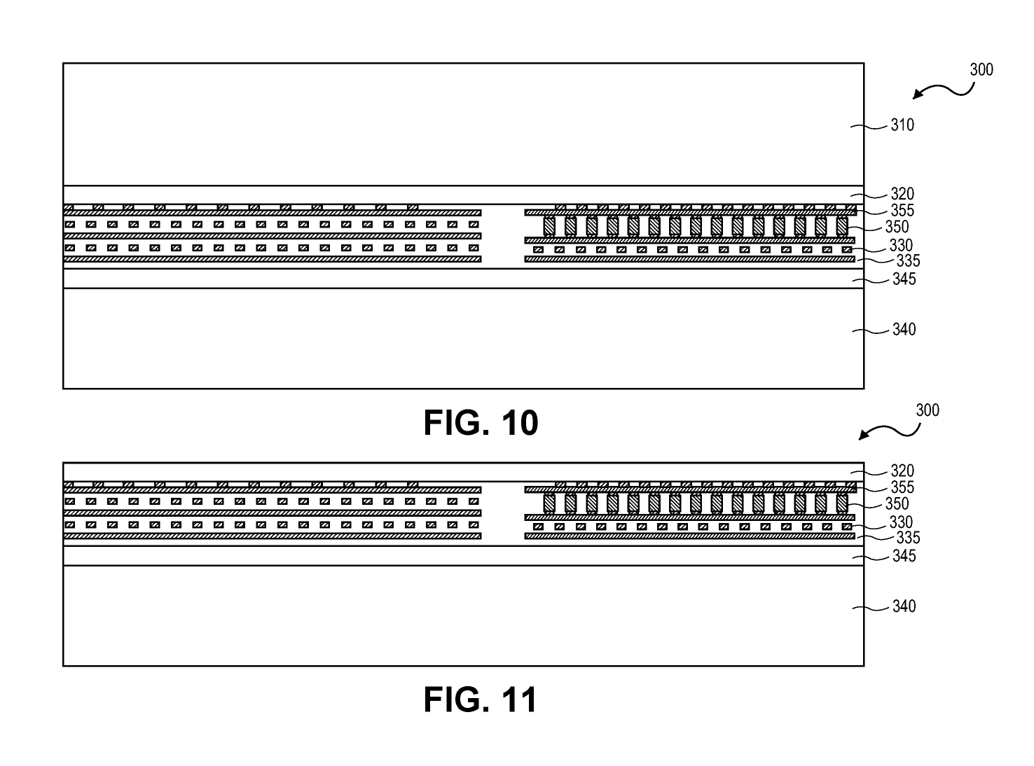

FIG. 10 shows the structure of FIG. 9 following the connection of the structure to a carrier wafer. In one embodiment, structure 300 from FIG. 9 is inverted and bonded to a carrier wafer. FIG. 10 shows carrier wafer 340 of, for example, a silicon or ceramic or other suitable substrate. Overlying a surface of carrier wafer 340, in one embodiment, is dielectric material layer 345 of, for example, an oxide. FIG. 10 shows the bonding through the dielectric materials (dielectric bond) and illustrates plurality of interconnects 330 juxtaposed to carrier wafer 340.

FIG. 11 shows the structure of FIG. 10 following the removal of a portion of substrate 310 from the structure. In one embodiment, a portion of substrate 310 is removed to expose device layer 320. Substrate 310 may be removed by mechanical (e.g., grinding) or other mechanism (e.g., etch). FIG. 11 shows device layer 320 including an exposed top surface of the structure (as viewed).

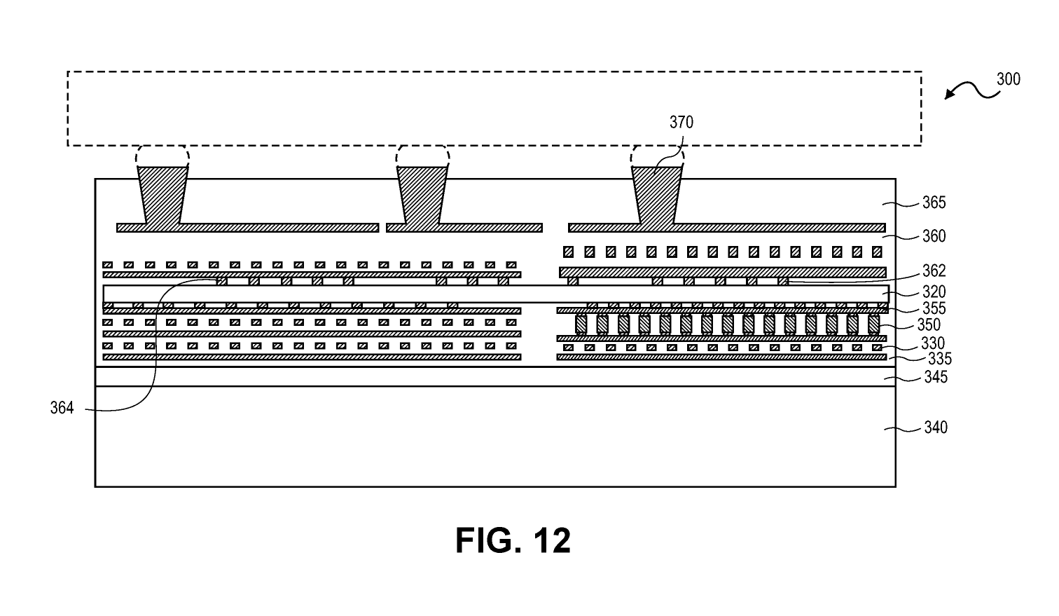

FIG. 12 shows the structure of FIG. 11 following the introduction of plurality of interconnects 360 on the structure. As illustrated, a surface of device layer 320 juxtaposed to plurality of interconnects 360 is passivated. In one embodiment, ones of plurality of interconnects 360 are connected to ones of memory devices 350 (e.g., through device layer 320). Such interconnects, in one embodiment, have dimensions that are larger than (e.g., thicker than) plurality of interconnects 330 that are similarly connected to memory devices 350. FIG. 12 shows contacts 362 connecting ones of plurality of interconnects 360 to respective ones of memory devices 350. FIG. 12 also shows device level contacts 364 connecting ones of plurality of interconnects 360 to devices in device layer 320. It is noted that, in one embodiment, where such ones of interconnects of plurality of interconnects 360 that are connected to devices in device layer 320 may have dimensions (e.g., thickness) that is compatible with devices in the device layer (e.g., impedance match). Plurality of interconnects 360 are selected, in one embodiment, from a material such as copper introduced by plating process with contacts 362 and contacts 364 to representatively being a copper or tungsten material and contacts between interconnects representatively being a copper material. FIG. 12 shows plurality of interconnects 360 isolated from one another and from device layer 320 in memory elements by a dielectric material such as an oxide.

FIG. 12 also shows the structure following the introduction of contact points 370 to ones of plurality of interconnects 360. Such contacts may be part of or an addition to a metallization layer disposed on structure. FIG. 12 further shows the structure for a passivation of the surface of the device with passivation layer 365 of, for example, an oxide. Contact points 370 may be used to connect structure 300 to a substrate, such as a package substrate. Once formed, the structure, if formed at a wafer level, may be singulated into a discreet monolithic 3D IC. FIG. 12 representatively shows structure 300 after singulation and illustrates in ghost lines the connection of the structure to a package substrate to solder connections to contacts points 370.

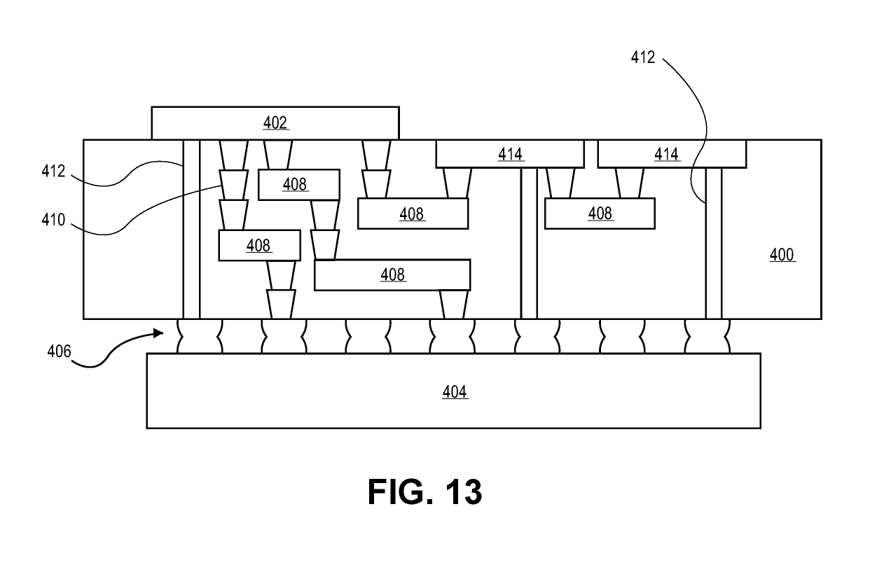

FIG. 13 illustrates an interposer 400 that includes one or more embodiments of the invention. The interposer 400 is an intervening substrate used to bridge a first substrate 402 to a second substrate 404. The first substrate 402 may be, for instance, an integrated circuit die. The second substrate 404 may be, for instance, a memory module, a computer motherboard, or another integrated circuit die. Generally, the purpose of an interposer 400 is to spread a connection to a wider pitch or to reroute a connection to a different connection. For example, an interposer 400 may couple an integrated circuit die to a ball grid array (BGA) 406 that can subsequently be coupled to the second substrate 404. In some embodiments, the first and second substrates 402/404 are attached to opposing sides of the interposer 400. In other embodiments, the first and second substrates 402/404 are attached to the same side of the interposer 400. And in further embodiments, three or more substrates are interconnected by way of the interposer 400.

The interposer 400 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 408 and vias 410, including but not limited to through-silicon vias (TSVs) 412. The interposer 400 may further include embedded devices 414, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 400.

In accordance with embodiments of the invention, apparatuses or processes disclosed herein may be used in the fabrication of interposer 400.

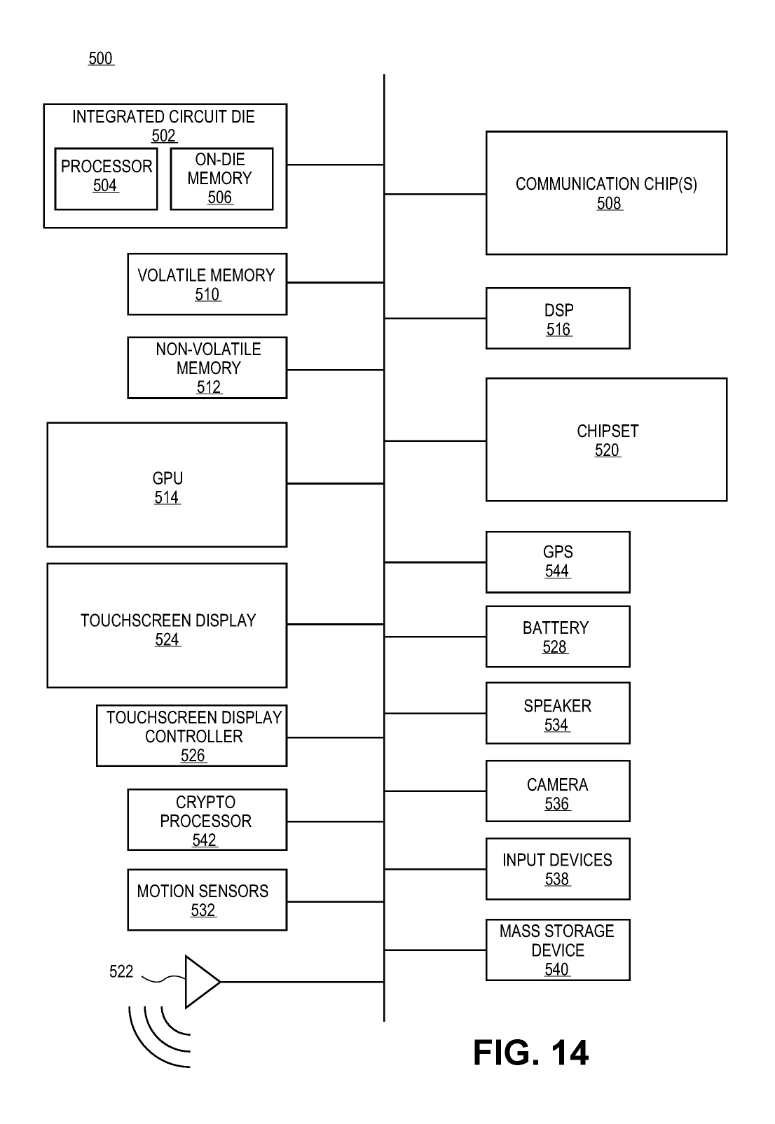

FIG. 14 illustrates a computing device 500 in accordance with one embodiment of the invention. The computing device 500 may include a number of components. In one embodiment, these components are attached to one or more motherboards. In an alternate embodiment, these components are fabricated onto a single system-on-a-chip (SoC) die rather than a motherboard. The components in the computing device 500 include, but are not limited to, an integrated circuit die 502 and at least one communication chip 508. In some implementations the communication chip 508 is fabricated as part of the integrated circuit die 502. The integrated circuit die 502 may include a CPU 504 as well as on-die memory 506, often used as cache memory, that can be provided by technologies such as embedded DRAM (eDRAM) or spin-transfer torque memory (STTM or STTM-RAM).

Computing device 500 may include other components that may or may not be physically and electrically coupled to the motherboard or fabricated within an SoC die. These other components include, but are not limited to, volatile memory 510 (e.g., DRAM), non-volatile memory 512 (e.g., ROM or flash memory), a graphics processing unit 514 (GPU), a digital signal processor 516, a crypto processor 542 (a specialized processor that executes cryptographic algorithms within hardware), a chipset 520, an antenna 522, a display or a touchscreen display 524, a touchscreen controller 526, a battery 528 or other power source, a power amplifier (not shown), a global positioning system (GPS) device 544, a compass 530, a motion coprocessor or sensors 532 (that may include an accelerometer, a gyroscope, and a compass), a speaker 534, a camera 536, user input devices 538 (such as a keyboard, mouse, stylus, and touchpad), and a mass storage device 540 (such as hard disk drive, compact disk (CD), digital versatile disk (DVD), and so forth).

The communications chip 508 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 508 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 508. For instance, a first communication chip 508 may be dedicated to shorter range wireless communications such as Wi-Fi and Bluetooth and a second communication chip 508 may be dedicated to longer range wireless communications such as GPS, EDGE, GPRS, CDMA, WiMAX, LTE, Ev-DO, and others.

The processor 504 of the computing device 500 includes a monolithic 3D IC including memory devices embedded in an interconnect region, that are formed in accordance with embodiment described above. The term “processor” may refer to any device or portion of a device that processes electronic data from registers and/or memory to transform that electronic data into other electronic data that may be stored in registers and/or memory.

The communication chip 508 may also include a monolithic 3D IC including memory devices embedded in an interconnect region, that are formed in accordance with embodiment described above.

In further embodiments, another component housed within the computing device 500 may contain a monolithic 3D IC including memory devices embedded in an interconnect region, that are formed in accordance with implementations described above.

### Examples

Example 1 is a method including forming a plurality of first interconnects and a plurality of second interconnects on opposite sides of an integrated circuit device layer including a plurality of circuit devices, wherein forming ones of the plurality of first interconnects and a plurality of second interconnects includes embedding memory devices therein; and coupling ones of the memory devices to each of respective ones of the plurality of first interconnects and the plurality of second interconnects and to ones of the plurality of circuit devices.

In Example 2, forming a plurality of first interconnects of Example 1 includes forming the plurality of first interconnects on an integrated circuit device layer of a first substrate and the method further includes coupling the first substrate to a second substrate wherein the plurality of first interconnects are juxtaposed to the second substrate; removing a portion of the first substrate to expose the circuit device layer; forming memory devices on the exposed circuit device layer; and forming the plurality of second interconnects on the exposed circuit device layer.

In Example 3, the dimensions of ones of the plurality of second interconnects of Example 2 are larger than dimensions of ones of the plurality of first interconnects.

In Example 4, the method of Example 3 includes forming contact points to ones of the plurality of second interconnects, the contact points operable for connection to an external source.

In Example 5, forming a plurality of first interconnects of Example 1 includes forming the plurality of first interconnects on an integrated circuit device layer of a first substrate and, prior to forming at least a portion of the plurality of first interconnects, the method further includes forming the plurality of circuit devices and forming memory devices, wherein ones of the memory devices are coupled to respective ones of the plurality of circuit devices.

In Example 6, after forming the plurality of first interconnects, the method of Example 5 includes coupling the first substrate to a second substrate wherein the plurality of first interconnects are juxtaposed to the second substrate; removing a portion of the first substrate to expose the circuit device layer; and forming the plurality of second interconnects on the exposed circuit device layer.

In Example 7, the dimensions of ones of the plurality of second interconnects of Example 1 are larger than dimensions of ones of the plurality of first interconnects.

In Example 8, the method of Example 6 includes forming contacts to ones of the plurality of second interconnects, the contact points operable for connection to an external source.

In Example 9, the memory devices of Example 1 include magnetoresistive random access memory devices.

Example 10 is a three-dimensional integrated circuit made by any of the methods of Examples 1-9.

Example 11 is an apparatus including a substrate including a plurality of first interconnects and a plurality of second interconnects on opposite sides of an integrated circuit device layer comprising a plurality of circuit devices, wherein ones of the plurality of first interconnects and a plurality of second interconnects includes memory devices embedded therein and ones of the memory devices are coupled to each of respective ones of the plurality of first interconnects and the plurality of second interconnects and to ones of the plurality of circuit devices.

In Example 12, the dimensions of ones of the plurality of second interconnects of Example 11 are larger than dimensions of ones of the plurality of first interconnects.

In Example 13, the apparatus of Example 12 includes contact points to ones of the plurality of second interconnects, the contact points operable for connection to an external source.

In Example 14, the memory devices of Example 11 magnetoresistive random access memory devices.

In Example 15, the memory devices of Example 12 are embedded in ones of the plurality of second interconnects.

In Example 16, the memory devices of Example 12 are embedded in ones of the plurality of first interconnects.

Example 17 is a method including forming a plurality of first interconnects on an integrated circuit device layer on a first substrate; coupling the first substrate to a second substrate wherein the plurality of first interconnects are juxtaposed to the second substrate; removing a portion of the first substrate to expose the circuit device layer; forming a plurality of second interconnects on the exposed circuit device layer; embedding memory devices in one of the plurality of first interconnects and the plurality of second interconnects; and coupling ones of the memory devices to each of respective ones of the plurality of first interconnects and the plurality of second interconnects and to ones of the plurality of circuit devices.

In Example 18, the memory devices of Example 17 are embedded in the plurality of first interconnects.

In Example 19, the memory devices of Example 17 are embedding the plurality of second interconnects.

In Example 20, the dimensions of ones of the plurality of second interconnects of Example 18 are larger than dimensions of ones of the plurality of first interconnects.

In Example 21, the method of Example 11 includes forming contact points to ones of the plurality of second interconnects, the contact points operable for connection to an external source.

Example 22 is a three-dimensional integrated circuit made by any of the methods of Examples 17-21.

In various embodiments, the computing device 1200 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1200 may be any other electronic device that processes data.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
forming a plurality of first interconnects and a plurality of second interconnects on opposite sides of an integrated circuit device layer comprising a plurality of circuit devices, wherein forming ones of the plurality of first interconnects and a plurality of second interconnects comprises embedding memory devices therein; and
coupling ones of the memory devices to each of respective ones of the plurality of first interconnects and the plurality of second interconnects and to ones of the plurality of circuit devices.

2. The method of claim 1, wherein forming a plurality of first interconnects comprises forming the plurality of first interconnects on an integrated circuit device layer of a first substrate and the method further comprises:
coupling the first substrate to a second substrate wherein the plurality of first interconnects are juxtaposed to the second substrate;
removing a portion of the first substrate to expose the circuit device layer;
forming memory devices on the exposed circuit device layer; and
forming the plurality of second interconnects on the exposed circuit device layer.

3. The method of claim 2, wherein dimensions of ones of the plurality of second interconnects are larger than dimensions of ones of the plurality of first interconnects.

4. The method of claim 3, further comprising forming contact points to ones of the plurality of second interconnects, the contact points operable for connection to an external source.

5. The method of claim 1, wherein forming a plurality of first interconnects comprises forming the plurality of first interconnects on an integrated circuit device layer of a first substrate and, prior to forming at least a portion of the plurality of first interconnects, the method further comprises forming the plurality of circuit devices and forming memory devices, wherein ones of the memory devices are coupled to respective ones of the plurality of circuit devices.

6. The method of claim 5, further comprising after forming the plurality of first interconnects, the method further comprises:
coupling the first substrate to a second substrate wherein the plurality of first interconnects are juxtaposed to the second substrate;
removing a portion of the first substrate to expose the circuit device layer; and
forming the plurality of second interconnects on the exposed circuit device layer.

7. The method of claim 1, wherein dimensions of ones of the plurality of second interconnects are larger than dimensions of ones of the plurality of first interconnects.

8. The method of claim 6, further comprising forming contacts to ones of the plurality of second interconnects, the contact points operable for connection to an external source.

9. The method of claim 1, wherein the memory devices comprise magnetoresistive random access memory devices.

10. (canceled)

11. An apparatus comprising:
a substrate comprising a plurality of first interconnects and a plurality of second interconnects on opposite sides of an integrated circuit device layer comprising a plurality of circuit devices, wherein ones of the plurality of first interconnects and a plurality of second interconnects comprises memory devices embedded therein and ones of the memory devices are coupled to each of respective ones of the plurality of first interconnects and the plurality of second interconnects and to ones of the plurality of circuit devices.

12. The apparatus of claim 11, wherein dimensions of ones of the plurality of second interconnects are larger than dimensions of ones of the plurality of first interconnects.

13. The apparatus of claim 11, further comprising contact points to ones of the plurality of second interconnects, the contact points operable for connection to an external source.

14. The apparatus of claim 11, wherein the memory devices comprise magnetoresistive random access memory devices.

15. The apparatus of claim 12, wherein the memory devices are embedded in ones of the plurality of second interconnects.

16. The apparatus of claim 12, wherein the memory devices are embedded in ones of the plurality of first interconnects.

17. A method comprising:
forming a plurality of first interconnects on an integrated circuit device layer on a first substrate;
coupling the first substrate to a second substrate wherein the plurality of first interconnects are juxtaposed to the second substrate;
removing a portion of the first substrate to expose the circuit device layer;
forming a plurality of second interconnects on the exposed circuit device layer;
embedding memory devices in one of the plurality of first interconnects and the plurality of second interconnects; and
coupling ones of the memory devices to each of respective ones of the plurality of first interconnects and the plurality of second interconnects and to ones of the plurality of circuit devices.

18. The method of claim 17, wherein the memory devices are embedded in the plurality of first interconnects.

19. The method of claim 17, wherein the memory devices are embedding the plurality of second interconnects.

20. The method of claim 17, wherein dimensions of ones of the plurality of second interconnects are larger than dimensions of ones of the plurality of first interconnects.

21. The method of claim 19, further comprising forming contact points to ones of the plurality of second interconnects, the contact points operable for connection to an external source.

22. (canceled)
